(19) United States
(12) Patent Application Publication
(10) Pub. No.: US 2013/0321038 A1
(43) Pub. Date: Dec. 5, 2013

(54) Drive way for FET

(71) Applicant: Wei Zhao, McKinney, TX (US)

(72) Inventor: Wei Zhao, McKinney, TX (US)

(21) Appl. No.: 13/986,737

(22) Filed: May 30, 2013

Related U.S. Application Data
(60) Provisional application No. 61/689,242, filed on Jun. 1, 2012.

(51) Int. Cl. H03K 17/06

(52) U.S. Cl. CPC H03K 17/063
USPC 327/109

(57) ABSTRACT

An apparatus and a method are provided to drive FET with voltage determined by current through the FET and parameters of FET to get maxim efficiency for any specific load current and variable load current; two versions of the invention are provided; one version of the invention is to provide an independent power supply with selected voltage value; the other version of the invention is to provide a controllable variable output voltage power supply to supply variable voltage to driver corresponding to variable load current.

### CROSS-REFERENCE TO RELATED APPLICATION

The present application claims priority to U.S. Provisional Patent Application No. 61/689,242 filed on Jun. 1, 2012, the entire contents of which are incorporated herein by reference.

### BACKGROUND

The following disclosure is related to electrical circuits and signal processing. Driver for FET is often used in switching power supply. Traditional driver supplied 5 volt voltage between gate and source of FET to turn on the FET no matter the current through FET or parameters of FET. Total loss of the FET is not minimized by this way.

### SUMMARY

Among FETs, Mosfet is often used as a switch in a switching power supply.

If the Mosfet is used as high side FET for buck converter, the total loss:

Ptotal=Pconduction+Pswitching+Pdrive+Poutput;

Conduction loss Pconduction=I*I*Rdson*Ton/Ts;

switching loss Psw=I*(Qgd/ig)*Vin*fs+I*(Qgs2/ig)*Vin*fs;

driving loss Pdrive=Qg*Vgs*fs;

output loss Poutput=Qoss*Vin*fs

If the Mosfet is used as low side Mosfet for buck converter.

The total loss:

Ptotal=Pconduction+Pdrive+Pdeadtime+Prr

Conduction loss: Pconduction=I*I*Rdson*Ton/Ts;

Driving loss: Pdrive=Qg*Vgs/fs;

Dead time loss: Pdeadtime=Io*Vfw*(Tdeadtime_on+Tdeadtime_off);

Reverse recovery charge: Prr=Qrr*Vin*fs

I is the current through Mosfet;

Rdson is the resistance between drain and source of Mosfet when Mosfet is on;

Qgd is gate-to-drain charge;

ig is the driving current supplied by driver to gate of Mosfet;

Vin is the input voltage of power supply;

fs is the switching frequency of power supply;

Qgs2 is post-Vth Gate-to-Source Charge;

Qg is the total gate charge of the Mosfet;

Vgs is the voltage supplied by driver to Mosfet between gate and source of the Mosfet;

Qoss is output charge of the Mosfet;

Qrr is reverse recovery charge of Mosfet;

Vfw is the forward voltage of body diode;

Tdeadtime_on is the dead time before Mosfet turns on;

Tdeadtime_off is the dead time before Mosfet turns off.

Ton is the time when Mosfet is on.

Ts is a switching period.

Usually Ton/Ts is replaced by d, d is duty cycle, d=Ton/Ts.

As above, only drive loss Pdrive and conduction loss Pconduction are related to Vgs.

Pdrive=Qg*Vgs*fs; Vgs increases, then Pdrive increases.

Pconduction=I*I*Rdson*Ton/Ts; Vgs increase, Rdson decreases, then Pconduction decreases. The change of Vgs does not affect other losses. There must be an optimum value of Vgs to cause Pdrive+Pconduction at minimum value. We select the optimum value of Vgs to drive Mosfet corresponding to the current and Mofet parameters.

In one way, the value of Vgs can be selected as the following:

Ploss(Vgs)=Pconduction+Pdrive=I*I*Rdson*Ton/Ts+Qg*Vgs*fs; (0)

Now we derive Rdson with Vgs. At triode mode of Mosfet,

I=K*[2*(Vgs−Vt)*Vds−Vds*Vds] (1);

I is the current through Mosfet;

Vgs is the voltage between gate and source of the Mosfet;

Vt is the threshold gate to source voltage value for Vgs of the Mosfet;

Vds is the voltage between drain and source of the Mosfet when MOSFET is on;

K is a device parameter of MOSFET given by:

K=0.5*Un*Cox*(W/L),

Un is a physical constant known as the electron mobility;

Cox is the capacitance per unit area of the gate-to-body capacitor for which the oxide layer serves as dielectric;

L is the length of the channel, and W is the channel's width.

We differentiate formula (1) and get

dI=K*dVds*[2*(Vgs−Vt)−2*Vds]=K*dVds*2*[(Vgs−Vt)−Vds],

dVds/dI=1/{2*K*[(Vgs−Vt)−Vds]},

at triode mode,

Vds is much smaller than Vgs or Vt, so Vds can be omitted. And dVds/dI=1/[2*K*(Vgs−Vt)], So Rdson=1/[2*K*(Vgs−Vt)]. Substitute into equation (0):

Ploss(Vgs)=I*I*Ton/Ts/[2*K*(Vgs−Vt)]+Qg*Vgs/fs,

let

d=Ton/Ts,

dPloss(Vgs)/dVgs=Qg*fs−I*I*d/[2*K*(Vgs−Vt)*(Vgs−Vt)]=0,

Vgs=Vt+I*sqrt(d/(Qg*fs*2*K)),

So optimum Vgs value is determined to get much higher efficiency than Vgs=5 volt.

In one implementation, the controlled variable output voltage power supply or biasing power supply select the optimum voltage value as Vt+I*sqrt(d/(Qg*fs*2*K)) corresponding to current I through FET and parameters of FET. When current change, the corresponding voltage also change.

Sqrt(x) is a square root function and returns a square root of X.

In second implementation, for a varying current load, Vgs is selected higher than 5 volt and less than gate to source rating voltage of the Mosfet for high load current through FET which is higher than (5−Vt)*sqrt(Qg*fs*2*K/d); Vgs is selected lower than 5 volt and higher than gate to source threshold voltage Vgs of Mosfet for low current through FET which is lower than (5−Vt)*sqrt(Qg*fs*2*K/d).

When depletion mode FET is used, the voltage is changed to negative.

### DESCRIPTION OF DRAWINGS

FIG. 1 is a conventional switching power supply block diagram with 5 volt driver voltage (prior art).

FIG. 2 is the invention 200 block diagram with predetermined voltage power supply in which voltage is constant for driver.

FIG. 3 is the invention 300 block diagram with a controlled variable output voltage power supply in which voltage is varying corresponding to current through FET and parameters of FET.

FIG. 4 is a method for operating the invention 300 power supply of FIG._3.

FIG. 5 is one implementation of invention 200 with a buck converter.

FIG. 6 is one implementation of invention 300 with a buck converter.

FIG. 7 is voltage waveform of gate to source voltage Vgs of high side MOSFET and low side MOSFET for conventional buck converter.

FIG. 8 is voltage waveform of gate to source voltage Vgs of high side MOSFET and low side MOSFET of invention 200 and invention 300 for buck converter.

### DETAILED DESCRIPTION

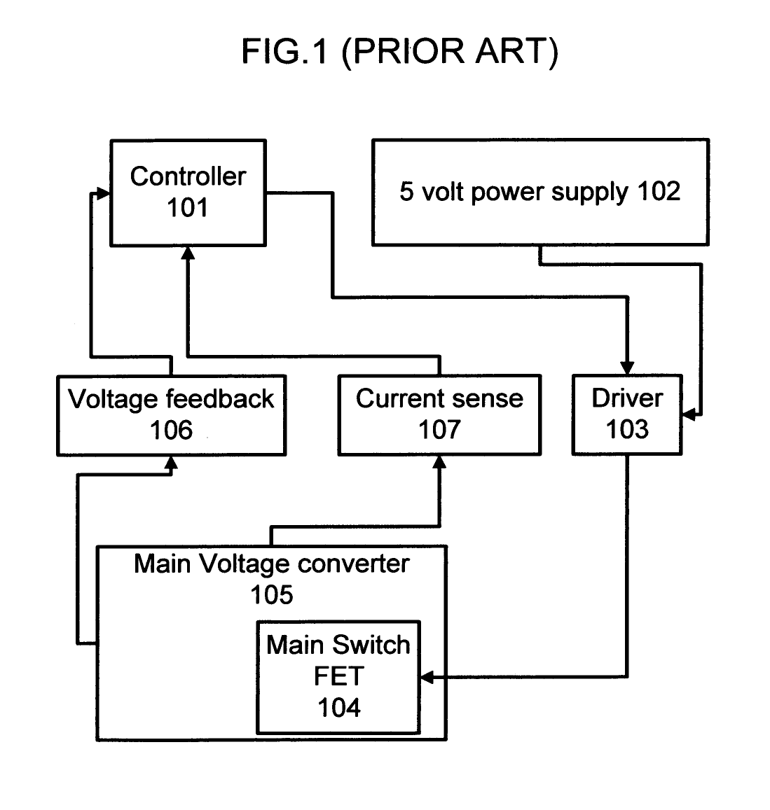

FIG. 1 is a conventional switching power supply block diagram with 5 volt driver voltage. Controller 101 controls driver 103 to turn on Main Switch FET 104 of main power converter 105 with 5 volt. Voltage feedbacks 106 feeds voltage back to controller 101 to keep output voltage constant. Current sense circuit 107 senses the current through FET to turn off Main Switch FET 104 at over current condition.

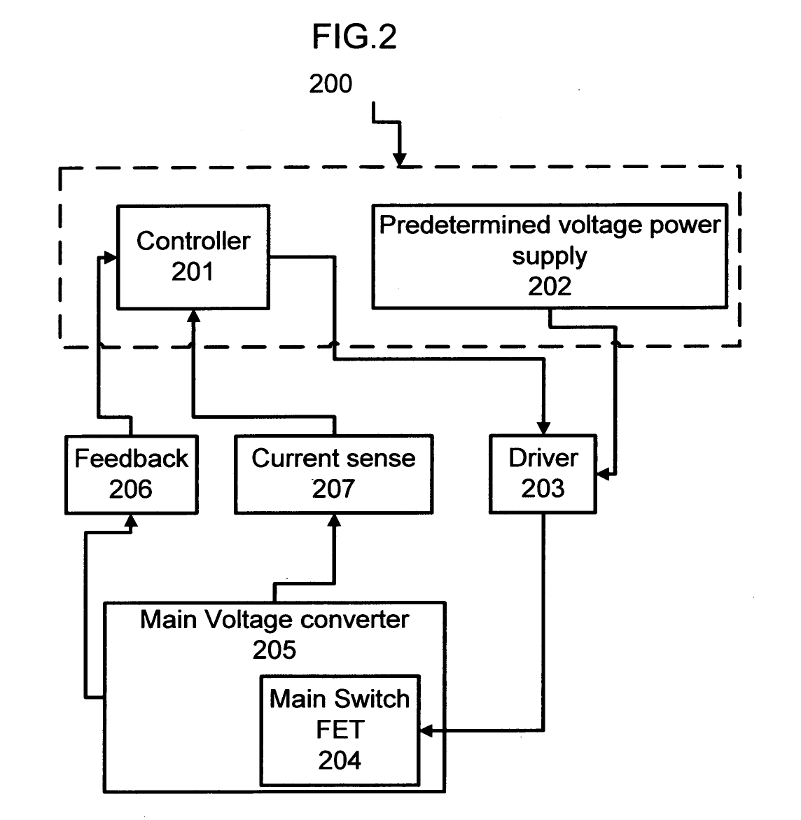

FIG. 2 is a block diagram of invention 200. For a known almost constant current through FET, the predetermined voltage value is selected corresponding to the specific current through FET and parameters of Main switch FET. In one implementation, driver voltage equals to Vt+I*sqrt(d/(Qg*fs*2*K)); For a varying current through FET, driver voltage is selected higher than 5 volt and less than gate to source rating voltage of the Mosfet for high current through FET that is greater than (5−Vt)*sqrt(Qg*fs*2*K/d), driver voltage is selected lower than 5 volt and higher than gate to source threshold voltage Vgs of Mosfet for low current through FET which is smaller than (5−Vt)*sqrt(Qg*fs*2*K/d), The predetermined voltage power supply 202 supplies voltage with selected value to driver 203. Driver 203 supplies voltage with selected value across gate and source of Main Switch FET 204 to increase efficiency. Controller 201 controls driver 203 to turn on Main Switch FET 204 of main power converter 205 with predetermined voltage value. Voltage feedback 206 feeds voltage back to controller 201 to keep output voltage constant. Current sense circuit 207 senses the current through FET to turn off Main Switch FET 204 at over current condition.

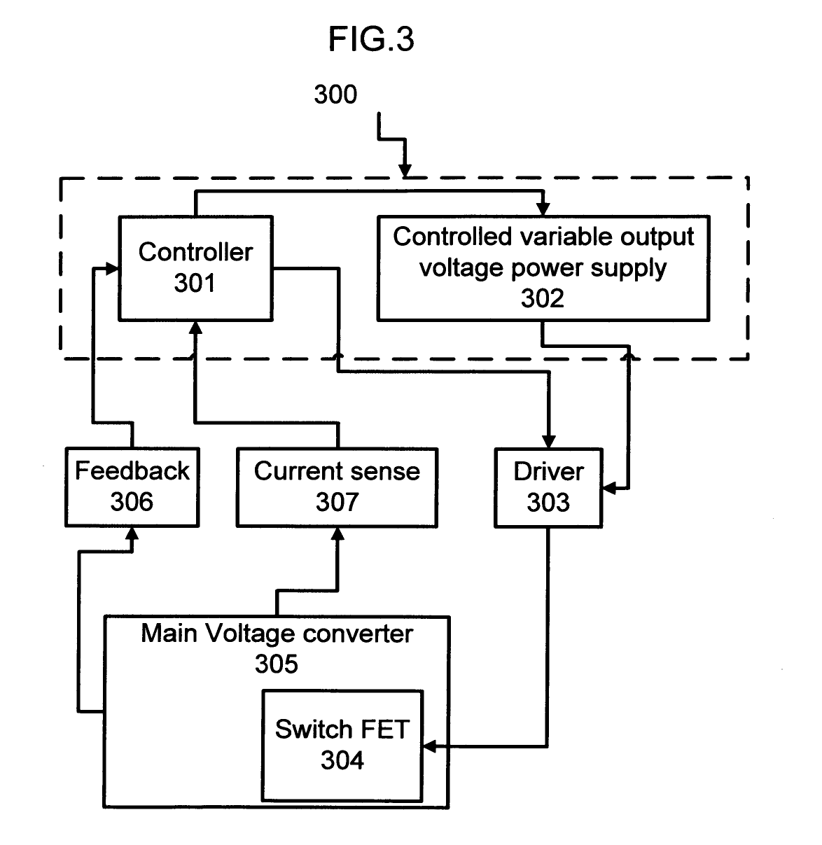

FIG. 3 is a block diagram for invention 300. A controlled variable output voltage power supply 302 is used. In one implementation, current sense 307 senses the current through FET and sends a signal to controller 301; controller 301 selects a voltage value Vm corresponding to the current through main switch FET 304 and parameters of FET 304, then sends a signal to the controlled variable output voltage power supply 302 to generate a voltage at value Vm. The controlled variable output voltage power supply 302 supplies a voltage at value Vm to driver 303. Driver 303 supplies voltage at value Vm across gate and source of Main Switch FET 304. The gate to source voltage of Main Switch FET 304 is varying corresponding to varying current through Main Switch FET 304 and parameters of Main Switch FET 304. The gate to source voltage of Main Switch FET 304 is constant corresponding to constant current through Main Switch FET 304 and parameters of Main Switch FET 304. In one implementation, driver 303 turns on Main Switch FET 304 with voltage equals to Vt+I*sqrt(d/(Qg*fs*2*K)); For a varying current through FET 304, driver voltage is selected higher than 5 volt and less than gate to source rating voltage of the FET for high current through FET that is greater than (5−Vt)*sqrt(Qg*fs*2*K/d), driver voltage is selected lower than 5 volt and higher than threshold voltage Vgs of FET for low current through FET which is smaller than (5−Vt)*sqrt(Qg*fs*2*K/d);

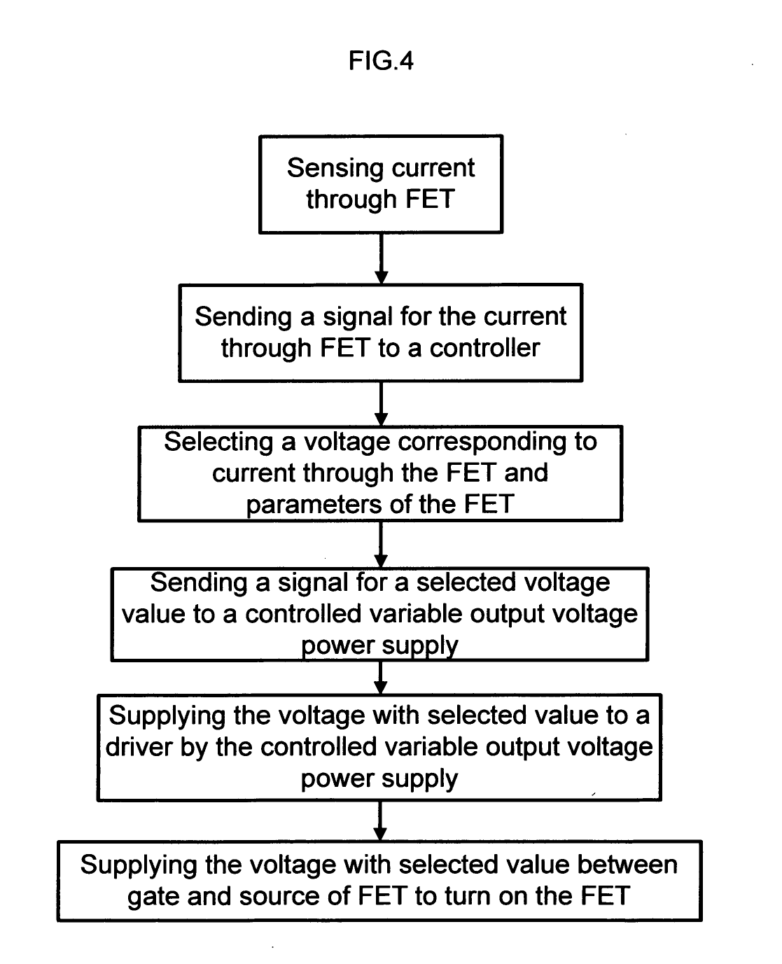

FIG. 4 is a method described to operate for invention 300. Firstly the current through FET is sensed and the signal is sent to controller; The controller selects the driving voltage corresponding to the current through FET; Next the controller generate the control signal for voltage value selected and send the signal to controlled power supply to generate the voltage with selected value; The controlled power supply applies the voltage with selected value on driver; finally the driver apply the voltage with selected value between gate and source of FET to turn on.

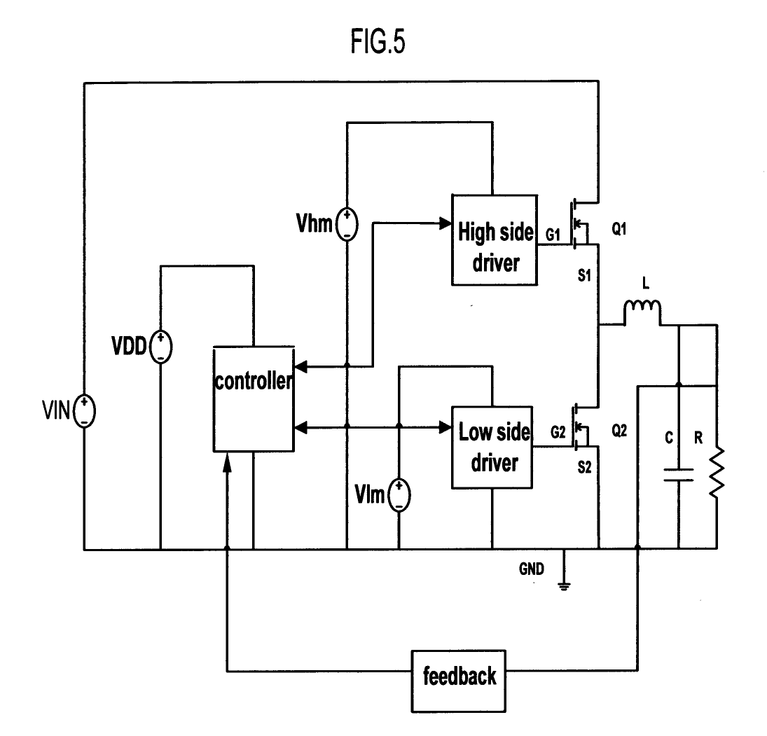

FIG. 5 is one implementation of invention 200 on buck converter. Vin is an input power supply, VDD is a biasing voltage power supply to supply voltage to controller. A power supply with voltage value Vhm is selected corresponding to current through Q1 to supply voltage to high side driver. A power supply with voltage value Vlm is selected corresponding to current through Q2 to supply voltage to low side driver. The loss is minimized and efficiency is increased. FET Q1 and FET Q2, inductor L, capacitor C and load R compose a buck converter. Feedback block feeds a voltage back to controller to keep the output voltage constant.

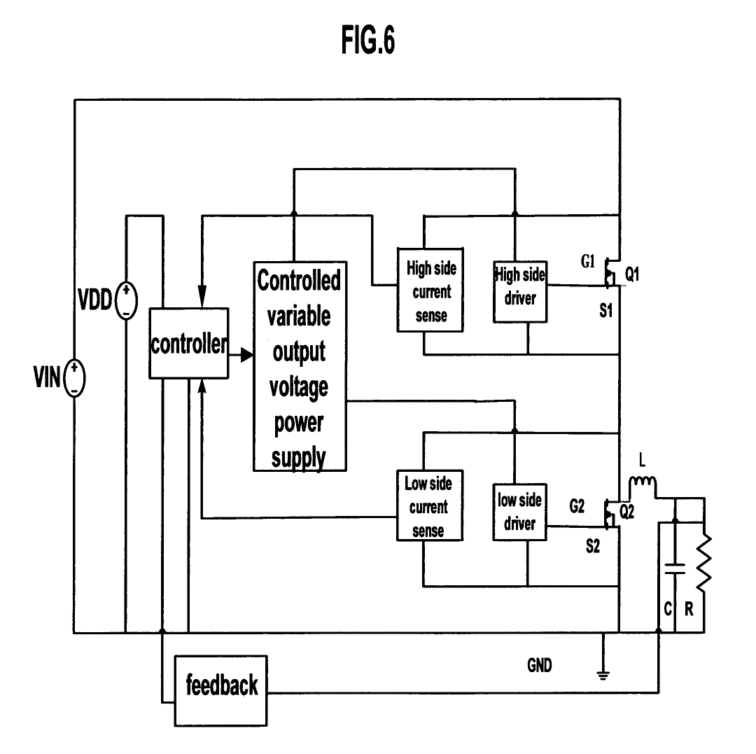

FIG. 6 is one implementation of invention 300 on buck converter. High side current sense circuit senses current through top FET Q1 and sends signal to controller; Low side current sense circuit senses current through bottom FET Q2 and sends signal to controller. Then the controller selects a voltage value Vh corresponding to current through Q1 for high side driver and selects a voltage value Vl corresponding to current through Q2 for low side driver respectively. Next the controller sends signals to a controlled variable output voltage power supply that have two output in which one output supplies a voltage with value Vh to high side driver and the other output supplies a voltage with value Vl to low side driver. So high side driver applies voltage Vh between gate and source of FET Q1 to turn on and low side driver applies voltage Vl between gate and source of FET Q2 to turn on. FET Q1, FET Q2, inductor L, capacitor C, load R compose a buck converter. Feedback block feeds voltage back to controller to keep output voltage constant. VIN is input voltage. VDD is a biasing power supply to supply voltage to controller. When current changes, the driver voltage also changes to minimize loss and improve efficiency.

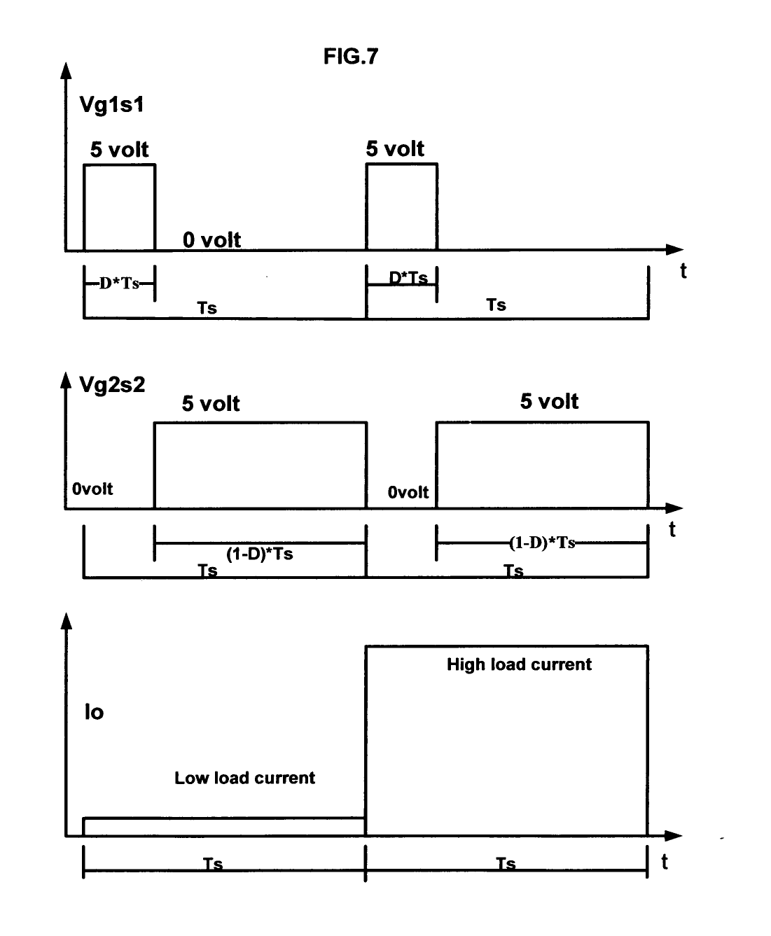

FIG. 7 is voltage waveform of high side driver and low side driver for conventional buck converter. No matter current through FET is high or low, the voltage Vhm for high side driver and the voltage Vlm for low side driver always are 5 volt. The voltage Vg1s1 between gate and source of FET Q1 is 5 volt and the voltage Vg2s2 between gate and source of FET Q2 is 5 volt.

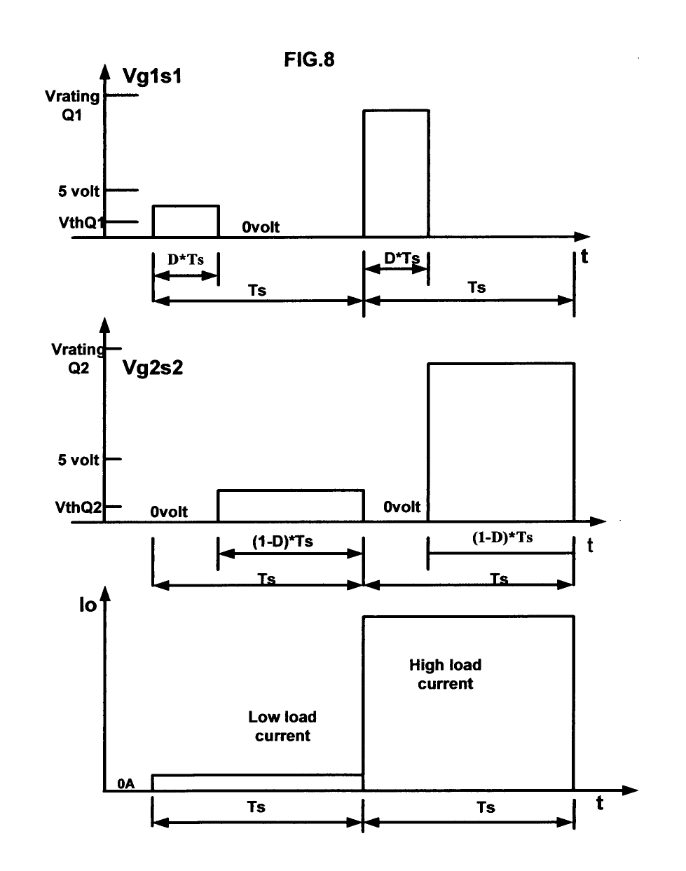

FIG. 8 is voltage waveform of high side driver and low side driver for one implementation of invention 200 and invention 300 on buck converter.

When the current through FET is lower than (5−Vt)*sqrt(2*K*Qg*fs/d), the gate to source voltages of high side FET and low side FET are greater than gate to source threshold voltage and less than 5 volt. VthQ1 is the gate to source threshold voltage Vgs of FET Q1, VthQ2 is the gate to source threshold voltage Vgs of FET Q2.

When the current through FET is higher than (5−Vt)*sqrt(2*K*Qg*fs/d), the gate to source voltages of high side FET and low side FET are greater than 5 volt and less than gate to source rating voltages. Vrating Q1 is the rating voltage between gate and source of FET Q1; Vrating Q2 is the rating voltage between gate and source of FET Q2.

In invention 200, Vg1s1 and Vg2s2 come from independent power supply with selected voltage value.

In invention 300, Vg1s1 and Vg2s2 come from controlled variable output voltage power supply in which voltage value is controlled by controller corresponding to current through FET and parameters of FET.

The topology discussed is based on buck. But the driver is not limited to buck topology. The invention is applied to all other topologies: forward, half-bridge, full bridge, boost, flyback, buck-boost, sepic, cuk, sepic fed buck and etc.

FET is MOSFET, JFET, MESFET, GaN FET, Si FET, GaAs FET or SiC FET.

What is claimed is:

1. An apparatus for a new drive comprising:
A main voltage converter 305 converts an input voltage to an output voltage at predetermined value;
A feedback 306 feeds output voltage back to controller 301 to keep output voltage constant at predetermined value;
A FET or many FETs are used as Switch FET 304 for switch in main voltage converter 305;
A current sense 307 senses current through switch FET 304;
A controller 301 operable to select a voltage value corresponding to current through FET 304 and parameters of FET 304 to turn on the switching FET 304;
A controlled variable output voltage power supply 302 is controlled by the controller 301 to supply the voltage with selected value to a driver 303;
The driver 303 turns on switch FET 304 with the selected voltage value.

2. A method of operation for an apparatus for a new drive, the method comprising:
sensing current through FET;
sending the signal for the current through FET to a controller;
selecting a voltage corresponding to current through the FET and parameters of the FET;
sending a signal for selected voltage value to a controlled variable output voltage power supply;
supplying the voltage with selected value to a driver by the controlled variable output voltage power supply;
supplying the voltage with selected value between gate and source of FET to turn on the FET.

3. The apparatus of claim 1, where in:
In one implementation, the FET is turned on with a voltage which value is Vt+I*sqrt(d/(Qg*fs*2*K)).

4. The apparatus of claim 1, where in:
FET is MOSFET, JFET, MESFET, GaN FET, Si FET, GaAs FET or SiC FET.

5. A method of operation for an apparatus for a new drive, the method comprising:
In one implementation, turning on a FET with a voltage higher than 5 volt and less than gate to source rating voltage of the FET for high load current which is higher than (5−Vt)*sqrt(Qg*fs*2*K/d); turning on a FET with a voltage lower than 5 volt and higher than gate to source threshold voltage of FET for low load current which is lower than (5−Vt)*sqrt(Qg*fs*2*K/d).

6. The method of claim 5, where in:
In one implementation, the FET is turned on with a voltage which value is Vt+I*sqrt(d/(Qg*fs*2*K)).

7. The method of claim 5, where in:
FET is MOSFET, JFET, MESFET, GaN FET, Si FET, GaAs FET or SiC FET.
